(19) United States
(12) Patent Application Publication
(10) Pub. No.: US 2026/0011706 A1
(43) Pub. Date: Jan. 8, 2026

(54) SEMICONDUCTOR PACKAGE

(71) Applicant: Samsung Electronics Co., Ltd., Suwon-si (KR)

(72) Inventors: Kyung Don Mun, Suwon-si (KR); Ji Hwang Kim, Suwon-si (KR)

(21) Appl. No.: 19/024,385

(22) Filed: Jan. 16, 2025

(30) Foreign Application Priority Data
Jul. 2, 2024 (KR) 10-2024-0086845

(51) Int. Cl. H01L 25/18; H01L 23/00; H01L 23/31; H01L 23/498; H01L 23/538; H01L 25/11

(52) U.S. Cl. CPC H01L 25/18; H01L 23/49816; H01L 23/5385; H01L 23/3107; H01L 24/16; H01L 25/117; H01L 2224/16227; H01L 2225/1094

(57) ABSTRACT

A semiconductor package has a first semiconductor package which includes a first redistribution structure, a first semiconductor chip on a lower surface of the first redistribution structure, a first encapsulant on at least a portion of the first semiconductor chip, a second redistribution structure on the first encapsulant, and a conductive post electrically connecting the first redistribution structure and the second redistribution structure through the first encapsulant; and a second semiconductor package which is on an upper surface of the first redistribution structure and comprises a third redistribution structure, a second semiconductor chip on the third redistribution structure, and a second encapsulant on at least a portion of the second semiconductor chip, wherein the first encapsulant integrally covers each of a lower surface and a side surface of the first semiconductor chip.

### CROSS-REFERENCE TO RELATED APPLICATION

This application claims priority to and the benefit of Korean Patent Application No. 10-2024-0086845, filed on Jul. 2, 2024, in the Korean Intellectual Property Office, the entire contents of which are incorporated herein by reference.

### BACKGROUND OF THE INVENTION

### (a) Field of the Invention

This disclosure is generally related to semiconductor packages.

### (b) Description of the Related Art

In response to the demand for miniaturization of an electronic device, such as a mobile device, a Package-On-Package POP structure is being used, in which a lower package including an application processor AP chip is connected to an upper package containing a memory chip in a vertically oriented arrangement. In the package-on-package structure, there may be a problem that heat generated from an AP chip with a high calorific value is difficult to effectively dissipate to the outside of the package due to the placement of the upper package on the lower package.

### SUMMARY OF THE INVENTION

As one aspect, the present disclosure may provide a semiconductor package having improved heat dissipation characteristics.

As another aspect, the present disclosure may provide a semiconductor package in which an electrical connection path between semiconductor chips is shortened.

According to another aspect, the present disclosure may provide a semiconductor package with improved electrical characteristics.

In an embodiment, a semiconductor package has a first semiconductor package which includes a first redistribution structure, a first semiconductor chip on a lower surface of the first redistribution structure, a first encapsulant on at least a portion of the first semiconductor chip, a second redistribution structure on the first encapsulant, and a conductive post electrically connecting the first redistribution structure and the second redistribution structure through the first encapsulant; and a second semiconductor package which is on an upper surface of the first redistribution structure and comprises a third redistribution structure, a second semiconductor chip on the third redistribution structure, and a second encapsulant on at least a portion of the second semiconductor chip, wherein the first encapsulant integrally covers each of a lower surface and a side surface of the first semiconductor chip.

In another embodiment, the present disclosure is to prove a semiconductor package having a first semiconductor package which includes a first redistribution structure, a memory chip on a lower surface of the first redistribution structure, a passive component spaced apart from the memory chip on the lower surface of the first redistribution structure, a first encapsulant on at least a portion of each of the memory chip and the passive component, a second redistribution structure on the first encapsulant, and a conductive post electrically connecting the first redistribution structure and the second redistribution structure through the first encapsulant; and a second semiconductor package which is on an upper surface of the first redistribution structure and comprises a third redistribution structure, a logic chip on the third redistribution structure, and a second encapsulant on at least a portion of the logic chip, wherein each of the memory chip, the passive component, and the conductive post may be electrically connected to the logic chip through the first redistribution structure and the third redistribution structure.

In another embodiment, the present disclosure is to prove a semiconductor package having a first redistribution structure, a first semiconductor chip on a lower surface of the first redistribution structure; a passive component on the lower surface of the first redistribution structure and spaced apart from the first semiconductor chip; a first encapsulant on at least a portion of each of the first semiconductor chip and the passive component; a second redistribution structure on the first encapsulant, a conductive post that electrically connects the first redistribution structure and the second redistribution structure through the first encapsulant; a second semiconductor chip on an upper surface of the first redistribution structure; and a second encapsulant on at least a portion of the second semiconductor chip, wherein the first encapsulant integrally covers each of a lower surface of the first semiconductor chip, a side surface of the first semiconductor chip, a lower surface of the passive component, and a side surface of the passive component.

According to one aspect of the present disclosure, a semiconductor package with improved heat dissipation characteristics may be provided.

According to another aspect of the present invention, a semiconductor package in which an electrical connection path between semiconductor chips is shortened may be provided.

According to another aspect of the present disclosure, a semiconductor package with improved electrical characteristics may be provided.

### BRIEF DESCRIPTION OF THE DRAWINGS

FIG. 1 is a cross-sectional view of a semiconductor package according to an embodiment of the present disclosure.

FIG. 2 is a cross-sectional view of a semiconductor package according to a comparative example.

FIG. 3 is a cross-sectional view of a semiconductor package according to another embodiment of the present disclosure.

FIG. 4 is a cross-sectional view of a semiconductor package according to another embodiment of the present disclosure.

FIG. 5 is a cross-sectional view of a semiconductor package according to another embodiment of the present disclosure.

FIG. 6 is a cross-sectional view of a semiconductor package according to another embodiment of the present disclosure.

FIGS. 7 to 18 are cross-sectional manufacturing process diagrams of the semiconductor package of FIG. 1.

FIG. 19 illustrates a state in which the semiconductor package of FIG. 1 is assembled with a main board and a thermal interface material.

### DETAILED DESCRIPTION OF THE EMBODIMENTS

Hereinafter, with reference to the accompanying drawing, several embodiments of the present disclosure will be described in detail so that a person of an ordinary skill can easily practice it in the technical field to which the present disclosure belongs. The present disclosure may be implemented in several different forms and is not limited to the embodiments described herein.

To clearly explain the present disclosure, parts that do not have a relationship with the explanation are omitted, and identical or similar components are assigned the same reference numerals throughout the specification.

In addition, the size and thickness of each component shown in the drawing are arbitrarily shown for better understanding and ease of description, so the present disclosure is not necessarily limited to what is shown. To clearly illustrate various layers and regions in the drawing, the thickness is enlarged. And in the drawings, for the convenience of explanation, the thickness of some layers and regions is exaggerated.

Throughout this specification, when a part is “connected” to another element, it may include not only being “directly connected” but also being “indirectly connected” with other members in between. From a similar perspective, it may include not only being “physically connected” but also being “electrically connected”.

In addition, when an element such as a layer, film, region, or substrate is referred to as being “above” or “on” another element, this may include not only the case where the other element is “directly on” but also the case where there is other element in the middle or an intervening element. In contrast, when an element is referred to as being “directly on” another element, it means that there is no other element in the middle or no intervening element. In addition, being “above” or “on” a reference part means being positioned above or below the reference part, and does not necessarily mean being positioned “above” or “on” it in the opposite direction of gravity.

In addition, when a part “includes” a component throughout the specification, unless explicitly described to the contrary, this means other components may be further included, rather than excluding other components unless otherwise stated.

In addition, throughout the specification, “on a plane” means when the target part is viewed from above, e.g., a plan view, and “cross-section” means the target part is vertically cut from the side exposing a cross-section of the part.

In addition, throughout the specification, the order of first, second, etc. is used to distinguish a component from another component that is the same or similar, and is not necessarily used to refer to a specific component. Therefore, a configuration referred to as the first component in a specific part of this specification may be referred to as the second component in another part of this specification.

In addition, throughout the specification, a singular reference to a component may include a plural reference to a plurality of components unless otherwise stated. For example, the “insulation layer” may be used to mean not only one insulation layer but also a plurality of insulation layers, such as two, three, or more.

For example, the “insulation layer” may be used to mean not only one insulation layer but also a plurality of insulation layers, such as two, three, or more.

As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

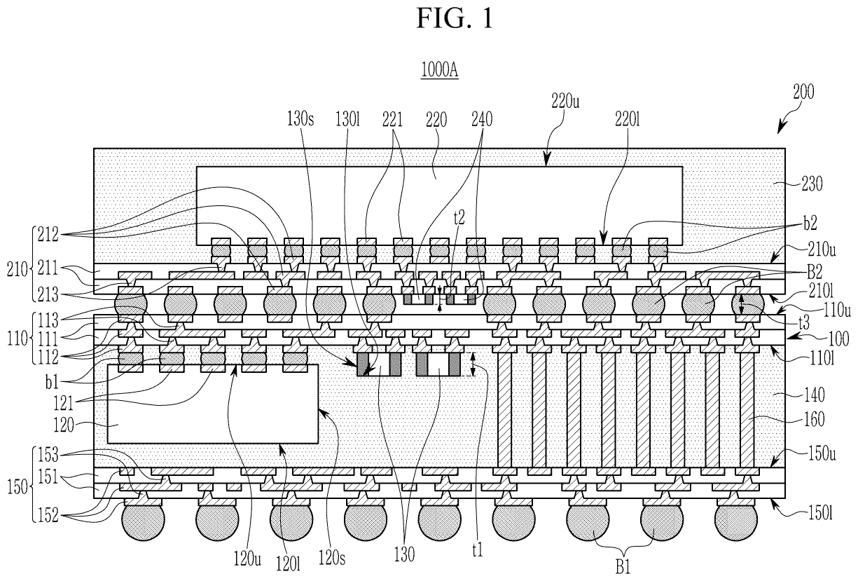

FIG. 1 is a cross-sectional view of a semiconductor package according to an embodiment of the present disclosure.

Referring to the drawings, the semiconductor package 1000A may include a first semiconductor package 100 and a second semiconductor package 200 disposed on the first semiconductor package 100.

The first semiconductor package 100 may include a first redistribution structure 110, a first semiconductor chip 120, a first passive component 130, a first encapsulant 140, a second redistribution structure 150, and a conductive post 160.

The first redistribution structure 110 may electrically connect the first semiconductor package 100 to the second semiconductor package 200, and may include an insulating layer 111, a wiring layer 112, and a via 113.

The insulating layer 111 may be disposed between the wiring layers 122 to prevent or reduce the likelihood of an electrical short circuit therebetween. The insulating layers 111 may have boundaries with each other depending on their materials and manufacturing processes or may not have boundaries that may be visually identified, i.e., prior to patterning, the insulating layer 111 may comprise a monolithic structure. As the material of the insulating layer 111, an insulating material may be used, for example, a thermoplastic resin, such as polyimide, a thermosetting resin such as epoxy, a photo-imaging dielectric (PID), and/or the like may be used. When PID is used as the material of the insulating layer 111, a fine pattern may be implemented through the application of a photo process.

The wiring layer 112 may include wiring pattern(s), and the wiring patterns may be connected to each other to perform various functions according to design. For example, the wiring layer 112 may include at least one of a signal wiring performing a signal transmission function, a power wiring performing a power transmission function, and a ground wiring performing a ground function. Among the wiring layers 112, the uppermost wiring layer and the lowermost wiring layer may include pads for electrical connection with other configurations. For example, the uppermost wiring layer may include pads for electrical connection with the second semiconductor package 200, and the lowermost wiring layer may include pads for electrical connection with the first semiconductor chip 120, the first passive component 130, and the conductive post 160. The number of wiring layers 112 is not limited and may be greater or less than that shown in FIG. 1. As the material of the wiring layer 112, a conductive material may be used, for example, copper (Cu), aluminum (Al), gold (Au), silver (Ag), platinum (Pt), tin (Sn), chromium (Cr), palladium (Pd), lead (Pb), titanium (Ti), tungsten (W), and/or an alloy thereof.

The via 113 penetrates or extends through the insulating layer 111 and may connect the wiring layers 112 positioned in different layers to each other. The via 113 may have a tapered shape or a cylindrical shape whose width becomes narrower from one side to the other side but is not limited thereto. As the material of the via 113, a conductive material may be used, and the same material as the material of the wiring layer 112 may be used. Depending on the manufacturing process, the via 113 may be integrally formed with the wiring layer 112, so that there may be no boundary therebetween, i.e., the via 113 and the wiring layer 112 form a monolithic structure.

The first semiconductor chip 120 may be disposed on the lower surface 1101 of the first redistribution structure 110 to be electrically connected to the first redistribution structure 110. In addition, the first semiconductor chip 120 may be electrically connected to the second semiconductor chip 220 through the first redistribution structure 110 and the third redistribution structure 210 and may also be electrically connected to the second redistribution structure 150 through the first redistribution structure 110 and the conductive post 160.

The first semiconductor chip 120 may include a connection pad 121. The connection pad 121 electrically connects the first semiconductor chip 120 to other configurations and may be formed of a conductive material, such as copper (Cu) and/or aluminum (Al).

In an embodiment, the first semiconductor chip 120 may be disposed in a face-up form such that the connection pad 121 is positioned on the upper surface 120u facing the first redistribution structure 110 on the first redistribution structure 110. The first semiconductor chip 120 may be bump-bonded on the first redistribution structure 110, for example, through a conductive bump b1. The conductive bump b1 may be disposed between the first redistribution structure 110 and the connection pad 121 to electrically connect the first redistribution structure 110 to the connection pad 121. The conductive bump b1 may be formed of a conductive material such as solder. The conductive bump b1 may be at least partially covered with a first encapsulant 140 or a separate underfill resin. As in an embodiment, the connection pad 121 of the first semiconductor chip 120 may be disposed to face the first redistribution structure 110 and may be connected to the first redistribution structure 110, thereby shortening an electrical connection path between the first semiconductor chip 120 and the second semiconductor chip 220.

To reduce or minimize an electrical connection path between the first semiconductor chip 120 and the second semiconductor chip 220, at least a portion of the first semiconductor chip 120 may vertically overlap the second semiconductor chip 220. In the present disclosure, ‘vertically’ overlapping means that the first semiconductor package 100 and the second semiconductor package 200 overlap in the stacked direction, e.g., in a direction perpendicular to the upper surface of the first redistribution structure 110u.

The first semiconductor chip 120 may include a chip, for example, a memory chip, which has a relatively lower calorific value compared to the second semiconductor chip 220. The memory chip may include one or more of a dynamic random-access memory (DRAM) chip, a static random-access memory (SRAM) chip, a flash memory chip, a high bandwidth memory (HBM) chip, a read-only memory (ROM) chip, or a magnetic random-access memory (MRAM) chip.

The number of the first semiconductor chips 120 is not particularly limited and may include a plurality of first semiconductor chips 120. A plurality of first semiconductor chips 120 may be disposed to be spaced apart from each other or may be stacked on each other.

The first passive component 130 may be disposed on the lower surface 1101 of the first redistribution structure 110 to be spaced apart from the first semiconductor chip 120 by a predetermined distance. The first passive component 130 may be electrically connected to the first redistribution structure 110 and may also be electrically connected to the second semiconductor chip 220 through the first redistribution structure 110 and the third redistribution structure 210. The first passive component 130 may be electrically connected to the second semiconductor chip 220 to improve electrical characteristics, such as power integrity (PI) of the second semiconductor chip 220. If necessary, the first passive component 130 may be electrically connected to the first semiconductor chip 120. The first passive component 130 may be bonded by surface mount technology (SMT) on the first redistribution structure 110 using, for example, solder paste. By mounting the first passive component 130 on the first redistribution structure 110 and connecting the first redistribution structure 110, an electrical connection path between the first passive component 130 and the second semiconductor chip 220 may be shortened.

To efficiently improve the power integrity PI of the second semiconductor chip 220 by reducing or minimizing the electrical connection path between the first passive component 130 and the second semiconductor chip 220, at least a portion of the first passive component 130 may vertically overlap the second semiconductor chip 220. In some embodiments, the entire first passive component 130 may vertically overlap the second semiconductor chip 220. To implement a structure in which the first passive component 130 and the second semiconductor chip 220 vertically overlap each other, when manufacturing the second semiconductor package 200, the conductive post 160 may be disposed to be biased toward one side of the lower package to provide placement space for the first semiconductor chip 120 and the first passive component 130, and therefore the first passive component 130 may be disposed on the inner side of the first semiconductor package 100. Accordingly, the first passive component 130 may be disposed between the first semiconductor chip 120 and the conductive post 160.

Because the first passive component 130 is embedded in the package, the thickness or number thereof may be freely designed. The thickness t1 of the first passive component 130 is not particularly limited but may be thicker than the thickness t2 of the second passive component 240. For example, the thickness of the first passive component 130 may be about 80 μm to 150 μm. The number of first passive components 130 is also not particularly limited, but may be designed to reduce or minimize the number of second passive components 240 and may be greater than the number of second passive components 240. For example, the number of the first passive components 130 may be 5 to 20.

The first passive component 130 may be suitable for improving power characteristics of the second semiconductor chip 220 and may include a capacitor, such as a multilayer ceramic capacitor (MLCC), a tantalum capacitor, or a silicon capacitor.

The first encapsulant 140 may be on and cover at least a portion of each of the first semiconductor chip 120 and the first passive component 130. For example, the first encapsulant 140 may integrally cover the bottom surface 1201 facing the second redistribution structure 150 of the first semiconductor chip 120, the side surface 120s of the first semiconductor chip 120, the bottom surface 1301 of the first passive component 130, and the side surface 130s of the first passive component 130, respectively. In the present disclosure, ‘integrally’ covering means continuously covering each component or area without distinction and without boundaries.

As the material of the first encapsulant 140, an insulating material such as an epoxy molding compound (EMC) may be used.

As described in the manufacturing process of the semiconductor package 1000A to be described below, the first encapsulant 140 may be formed after forming a conductive post 160 on the first redistribution structure 110 and arranging the first semiconductor chip 120 and the first passive component 130. Also, the second redistribution structure 150 may be directly formed on the first encapsulant 140. Therefore, the first encapsulant 140 contacts each of the first redistribution structure 110 and the second redistribution structure 150 and may fill at least a part of the space between the first redistribution structure 110 and the second redistribution structure 150. For example, the first encapsulant 140 may fill at least a portion of each of the space between the first semiconductor chip 120 and the second redistribution structure 150 and the space between the first passive component 130 and the second redistribution structure 150. Furthermore, the first encapsulant 140 may be on and cover at least a portion of a side surface of the conductive post 160.

The second redistribution structure 150 may be disposed on the first encapsulant 140 to electrically connect the first semiconductor package 100 to other components, such as a main board, and may include an insulating layer 151, a wiring layer 112, and a via 113. Unless the description of each of the insulating layer 151, the wiring layer 152, and the via 153 of the second redistribution structure 150 is particularly contradictory, the description of each of the insulating layer 111, the wiring layer 112, and the via 113 of the first redistribution structure 110 may be applied in the same manner.

A conductive bump B1 for electrically connecting the semiconductor package 1000A to another configuration, such as a main board, may be disposed on the lower surface 1501 of the second redistribution structure 150. The conductive bump B1 may be formed of a conductive material such as solder.

The conductive post 160 may penetrate or extend through the first encapsulant 140 to electrically connect the first redistribution structure 110 and the second redistribution structure 150. In addition, the conductive post 160 may electrically connect the second semiconductor chip 220 to the second redistribution structure 150 through the third redistribution structure 210 and the first redistribution structure 110. The conductive posts 160 may be formed of a conductive material, such as copper (Cu) and/or aluminum (Al). The number of conductive posts 160 may be greater or less than that shown in the drawing.

To shorten an electrical connection path between the conductive post 160 and the second semiconductor chip 220, at least a portion of the conductive post 160 may vertically overlap the second semiconductor chip 220.

The second semiconductor package 200 is disposed on the upper surface 110u of the first redistribution structure 110 to face the first redistribution structure 110, and may include a third redistribution structure 210, a second semiconductor chip 220, a second encapsulant 230, and a second passive component 240.

The third redistribution structure 210 may electrically connect the second semiconductor package 200 to the first semiconductor package 100, and may include an insulating layer 211, a wiring layer 212, and a via 213. Unless specifically contradicted by the description of each of the insulating layer 211, wiring layer 212, and vias 213 of the third redistribution structure 210, the description of each of the insulating layer 111, the wiring layer 112, and the via 113 of the first redistribution structure 110 may be applied in the same manner.

The second semiconductor chip 220 is disposed on the upper surface 210u of the third redistribution structure 210 and may include a second connection pad 221. The second semiconductor chip 220 may be disposed in a face down form, such that the second connection pad 221 is positioned on the lower surface 2201 facing the third redistribution structure 210 on the third redistribution structure 210. The second semiconductor chip 220, for example, may be bump-bonded on the third redistribution structure 210 through the conductive bump b2. The conductive bump b2 may be disposed between the third redistribution structure 210 and the second connection pad 221 to electrically connect the third redistribution structure 210 to the second connection pad 221. The conductive bump b2 may be formed of a conductive material, such as solder. The conductive bump b2 may be at least partially covered with a second encapsulant 230 or may be at least partially covered with a separate underfill resin. In other embodiments, the second semiconductor chip 220 may be wire-bonded on the third redistribution structure 210 through a conductive wire.

The second semiconductor chip 220 may include a chip, for example, a logic chip, which has a relatively higher calorific value compared to the first semiconductor chip 120. The logic chip may include one or more of an application processor (AP), a microprocessor, a central processing unit (CPU), a graphic processing unit (GPU), a natural processing unit (NPU), and/or an application specific integrated circuit (ASIC).

The second encapsulant 230 may be on and cover at least a portion of the second semiconductor chip 220. As the material of the second encapsulant 230, an insulating material, such as an epoxy molding compound (EMC) may be used.

A conductive bump B2 for electrically connecting the third redistribution structure 210 and the first redistribution structure 110 may be disposed on the lower surface 2101 of the third redistribution structure 210. The conductive bump b2 may be formed of a conductive material, such as solder.

The second passive component 240 may be disposed on the lower surface 2101 of the third redistribution structure 210 and in a space between the conductive bumps B2. The second passive component 240 may be electrically connected to the third redistribution structure 210 and may also be electrically connected to the second semiconductor chip 220 through the third redistribution structure 210. The second passive component 240 may be electrically connected to the second semiconductor chip 220 to improve electrical characteristics of the second semiconductor chip 220 together with the first passive component 130. In some embodiments, the first passive component 130 may be electrically connected to the first semiconductor chip 120. The second passive component 240 may be bonded to the third redistribution structure 210 by a surface mount technology SMT using, for example, a solder paste.

To efficiently improve the power integrity PI of the second semiconductor chip 220 by reducing or minimizing the electrical connection path between the second passive component 240 and the second semiconductor chip 220, at least a portion of the second passive component 240 may vertically overlap the second semiconductor chip 220. In some embodiments, the entire second passive component 240 may vertically overlap the second semiconductor chip 220.

The thickness t2 of the second passive component 240 may be thinner than the thickness t3 of the conductive bump B2 for ease of process, mechanical stability, thermal stability, and/or the like. For example, the thickness t2 of the second passive component 240 may be at least 35 μm thinner than the thickness t3 of the conductive bump B2. As a specific example, when the thickness t3 of the conductive bump B2 is about 125 μm, the thickness t2 of the second passive component 240 may be up to about 90 μm, and when the thickness t3 of the conductive bump B2 is about 135 μm, the thickness t2 of the second passive component 240 may be up to about 100 μm. In an embodiment, the thickness t2 of the second passive component 240 may be about 60 μm.

The number of second passive components 240 is not particularly limited, but may be designed in a small number to secure a sufficient conductive bump B2 arrangement space. From this point of view, the number of the second passive components 240 may be less than the number of the first passive components 130. For example, the number of the second passive components 240 may be five or less. According to embodiments, the second passive component 240 may not exist in the second semiconductor package 200.

The second passive component 240 may be suitable for improving power characteristics of the second semiconductor chip 220, and may include a thin film capacitor, such as a land side capacitor LSC.

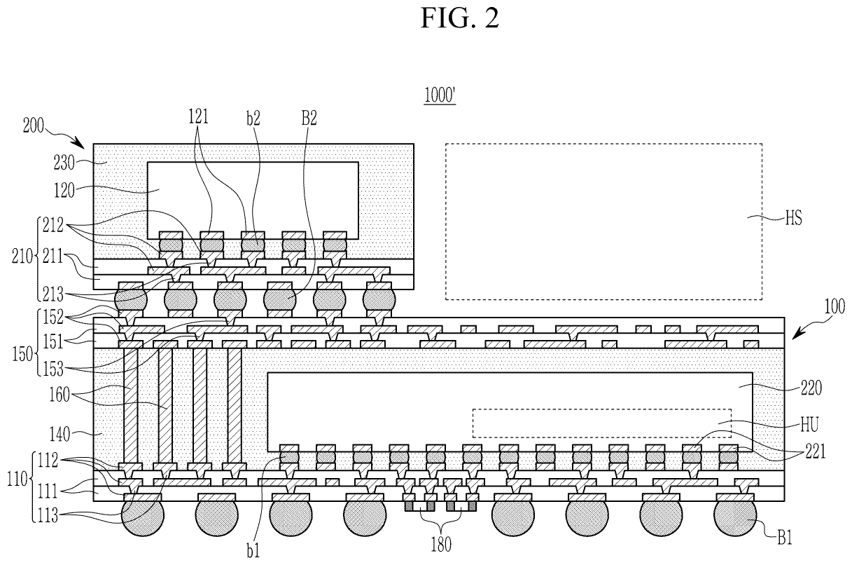

FIG. 2 is a cross-sectional view of a semiconductor package according to a comparative example.

In FIG. 2, the same reference numerals as in FIG. 1 are used for configurations that are the same as or similar to the semiconductor package 1000A according to an embodiment illustrated in FIG. 1.

In the case of the semiconductor package 1000′ according to the comparative example, an AP chip 220 having a high calorific value is disposed in the lower package 100, and a memory chip 120 having a low calorific value is disposed in the upper package 200. The AP chip 220 and the memory chip 120 are bump-bonded on the first redistribution structure 110 and the third redistribution structure 210, respectively, and may be connected through the conductive post 160 and the redistribution structures 110, 150, and 210.

In this case, to dissipate heat generated from the AP chip 220 having a high calorific value to the outside of the package, a method of arranging a heat slug HS in parallel with the upper package may be considered on the lower package. To increase or maximize the heat dissipation effect through the heat slug HS, the CPU block HU, which has a particularly high calorific value in the AP chip 220, may be configured to vertically overlap the heat slug HS. However, this may not only limit the design freedom of the AP chip 220, but may also increase the electrical connection path and latency between the CPU block HU and the memory chip 120. Additionally, because the upper package is mounted in an asymmetric form that is skewed on one side of the lower package to secure the arrangement space of the heat slug HS, process problems, such as ball joint issues between the upper package and the lower package may arise.

In addition, to improve the power integrity PI of the AP chip 220, a method of mounting the capacitor 180 together with the conductive bump B 2 on the lower surface of the lower package and connecting to the blocks such as the CPU, GPU, and NPU in the AP chip 220 may be considered. An increase in the number of capacitors 180 may lead to a decrease in the number of conductive bumps B1 for power supply, resulting in a weakening of the power distribution network (PDN) at the system level. In addition, there is a problem that the thickness of the capacitor 180 mounted together with the conductive bump B1 is limited to less than or equal to the thickness of the conductive bump B1.

According to embodiments of the present disclosure, however, heat dissipation characteristics can be improved by placing a second semiconductor chip 220 (e.g., AP chip) with a high calorific value in the upper package, which is the second semiconductor package 200, and the thermal interface material may be directly bonded on the upper package without a heat slug. Additionally, the location of the block (e.g., CPU block) in the second semiconductor chip 220 is not limited due to the heat slug, and the electrical connection path between the second semiconductor chip 220 and the first semiconductor chip 120 may be reduced or minimized by arranging the first semiconductor chip 120 in a face-up form.

Furthermore, according to embodiments of the present disclosure, the power integrity PI of the second semiconductor chip 220 can be improved by embedding the first passive component 130 in the first semiconductor package 100 and electrically connecting it to the second semiconductor chip 220 through a short path. Through the embedding of the first passive component 130, the number of second passive components 240 disposed on the lower surface of the second semiconductor package 200 may be reduced, and the number of conductive bumps B2 functioning as I/O terminals (e.g., I/O terminals for power supply) of the second semiconductor package 200 may be increased. Embedding of the first passive component 130 and an increase in the number of conductive bumps B2 may contribute to improving the power integrity PI of the second semiconductor chip 220.

In addition, as described in the manufacturing process described below, the semiconductor package 1000A may be manufactured by separately manufacturing the first semiconductor package 100 and the second semiconductor package 200 and then bonding them. Therefore, after manufacturing the first semiconductor packages 100 and the second semiconductor packages 200, the manufactured packages may be tested and only good packages may be selected, and then bonded except for defective packages, thereby reducing or minimizing chip loss.

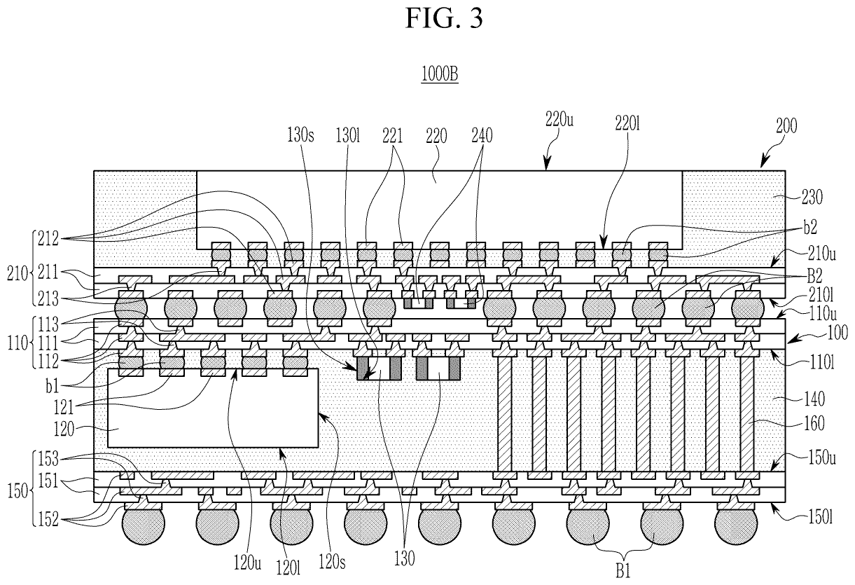

FIG. 3 is a cross-sectional view of a semiconductor package according to another embodiment of the present disclosure.

In the semiconductor package 1000B, the upper surface 220u of the second semiconductor chip 220 may be at least partially exposed from the second encapsulant 230. The upper surface 220u of the second semiconductor chip 220 may be at least partially exposed from the second encapsulant 230, for example by grinding the second encapsulant 230. With the structure in which the upper surface 220u of the second semiconductor chip 220 is at least partially exposed, a semiconductor package having better heat dissipation characteristics may be provided.

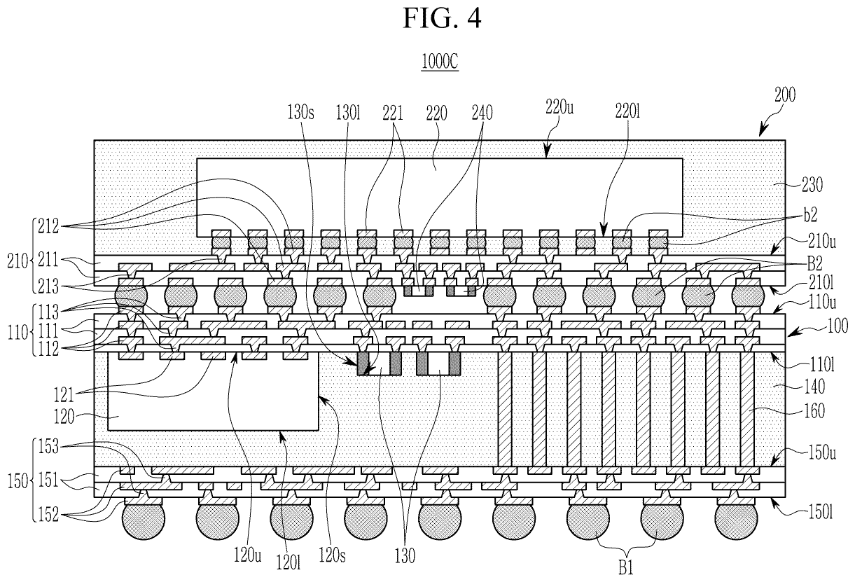

FIG. 4 is a cross-sectional view of a semiconductor package according to another embodiment of the present disclosure.

In the semiconductor package 1000C, the first semiconductor chip 120 may be directly disposed on the first redistribution structure 110, and the connection pad 121 of the first semiconductor chip 120 may be connected in contact with the first redistribution structure 110. For example, the connection pad 121 of the first semiconductor chip 120 may be connected to the via 113 of the first redistribution structure 110. By directly connecting the connection pad 121 of the first semiconductor chip 120 to the first redistribution structure 110, it is possible to reduce the thickness and provide a semiconductor package having a fine pitch.

In addition, as long as the description of the semiconductor package 1000C is not particularly contradictory, the detailed description of the description of the semiconductor package 1000A may be applied in the same manner.

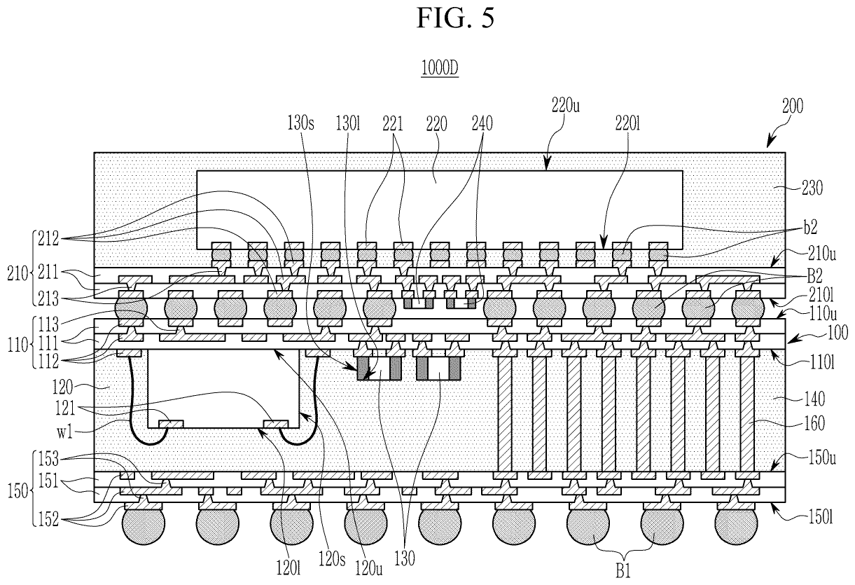

FIG. 5 is a cross-sectional view of a semiconductor package according to another embodiment of the present disclosure.

In the semiconductor package 1000D, the connection pad 121 may be disposed on the lower surface 1201 of the first semiconductor chip 120 and may be electrically connected to the first redistribution structure 110 through a conductive wire w1. The conductive wire w1 may be formed of a conductive material, such as copper (Cu) and/or aluminum (Al). An adhesive member, such as a die attach film (DAF), for attaching them to each other may be disposed between the first semiconductor chip 120 and the first redistribution structure 110.

In addition, as long as the description of the semiconductor package 1000D is not particularly contradictory, the detailed description of the description of the semiconductor package 1000A may be applied in the same manner.

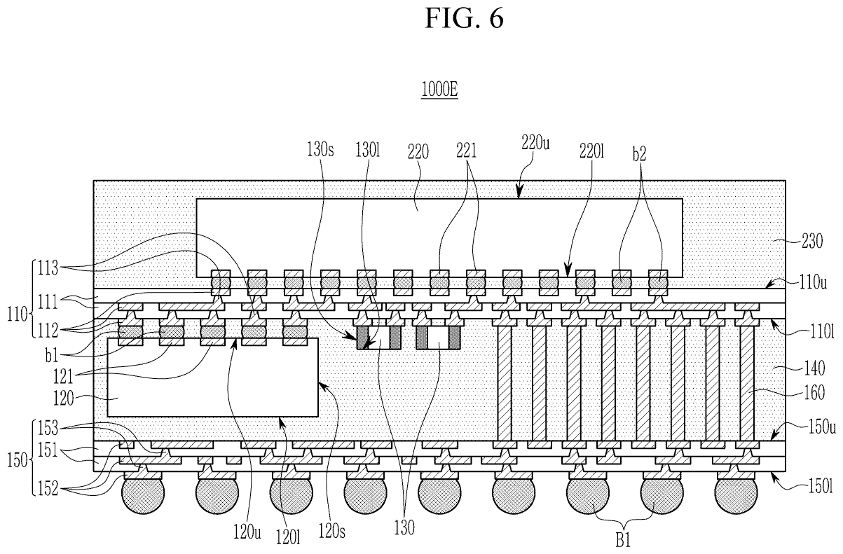

FIG. 6 is a cross-sectional view of a semiconductor package according to another embodiment of the present disclosure.

The semiconductor package 1000E may include a first redistribution structure 110, a first semiconductor chip 120, a first passive component 130, a first encapsulant 140, a second redistribution structure 150, a conductive post 160, a second semiconductor chip 220, and a second encapsulant 230. In the case of the semiconductor package 1000E, the third redistribution structure 210 is omitted so that the second semiconductor chip 220 is directly disposed on the first redistribution structure 110. As the third redistribution structure 210 is omitted, the conductive bump B2 for electrically connecting the third redistribution structure 210 to the first redistribution structure 110 may also be omitted.

In the semiconductor package 1000E, the second semiconductor chip 220 is disposed on the upper surface 110u of the first redistribution structure 110. The second semiconductor chip 220, for example, may be bump-bonded on the first redistribution structure 210 through the conductive bump b2. As the third redistribution structure 210 is omitted, the second semiconductor chip 220 may be electrically connected to each of the first semiconductor chip 120, the first passive component 130, and the conductive post 160 through a shorter path.

In addition, as long as the description of the semiconductor package 1000E is not particularly contradictory, the detailed description of the description of the semiconductor package 1000A may be applied in the same manner.

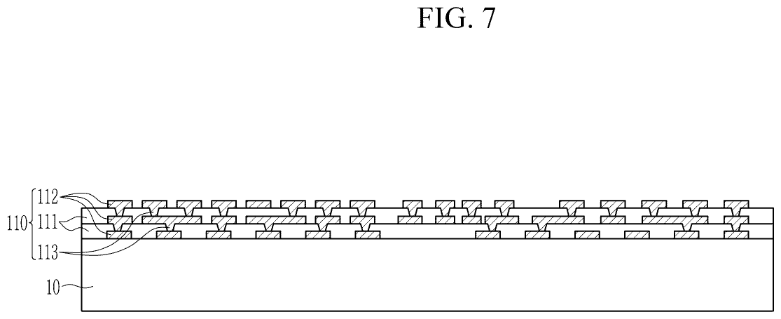

FIGS. 7 to 18 are cross-sectional manufacturing process diagrams of the semiconductor package of FIG. 1.

First, referring to FIG. 7, a first redistribution structure 110 is formed. The first redistribution structure 110 may be formed on the carrier substrate 10. The first redistribution structure 110 may be manufactured by sequentially and repeatedly forming the insulating layer 111, the via 113, and the wiring layer 112 as necessary.

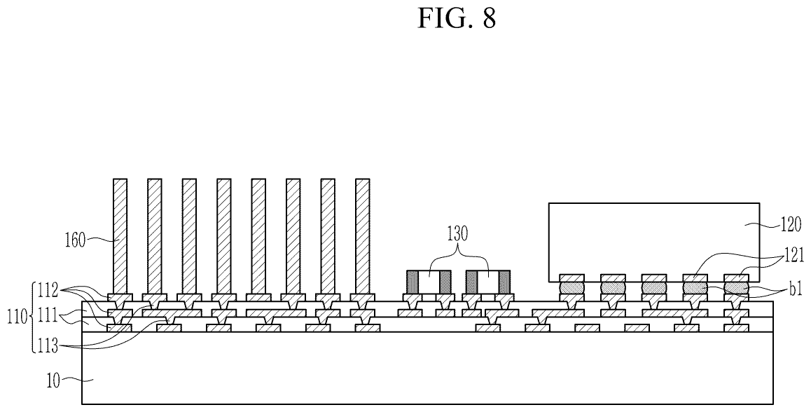

Next, referring to FIG. 8, a conductive post 160 is formed on the first redistribution structure 110, and the first semiconductor chip 120 and the first passive component 130 are disposed on the first redistribution structure. The conductive post 160 may be formed through a known plating process, and may be formed before the first semiconductor chip 120 and the first passive component 130 are disposed, but is not limited thereto.

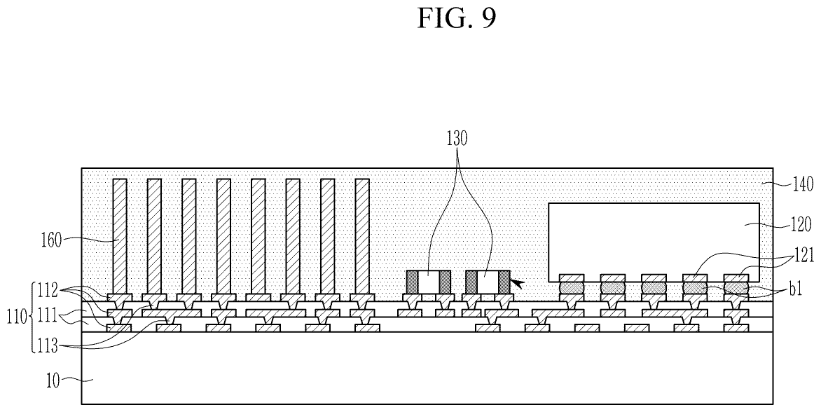

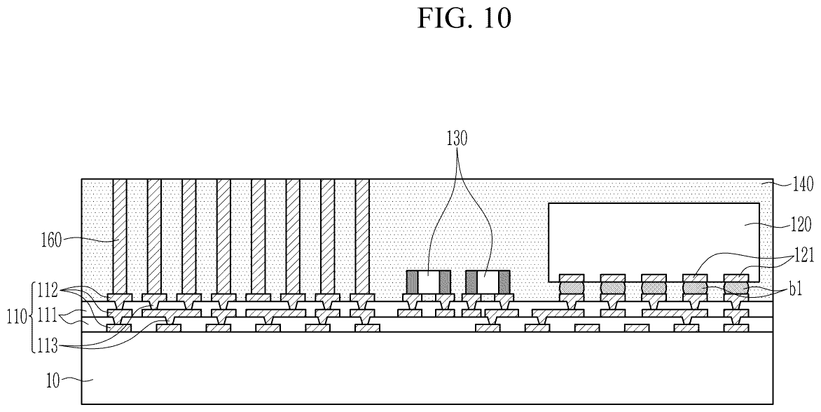

Next, referring to FIGS. 9 and 10, a first encapsulant 140 is formed on and at least partially covering the conductive post 160, the first semiconductor chip 120, and the first passive component 130, and then grinding the upper surface of the first encapsulant 140 to at least partially expose the conductive post 160. The first encapsulant 140 may be formed by compression molding, transfer molding, and/or the like.

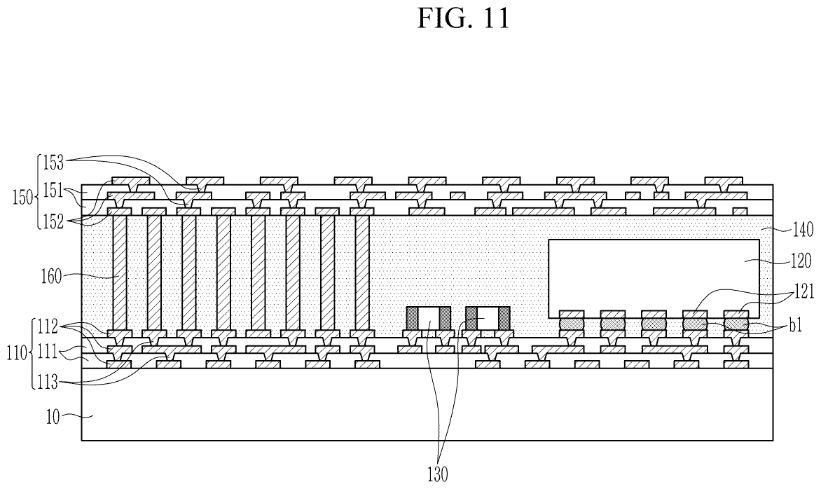

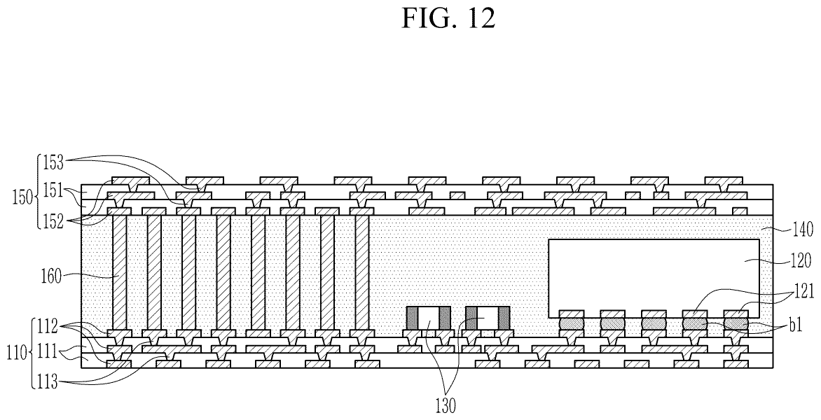

Next, referring to FIGS. 11 and 12, the first semiconductor package 100 is manufactured by forming a second redistribution structure 150 on the first encapsulant 140 and removing the carrier substrate 10. Similar to the first redistribution structure 110, the second redistribution structure 150 may be manufactured by sequentially and repeatedly forming the insulating layer 151, the via 153, and the wiring layer 152 as necessary.

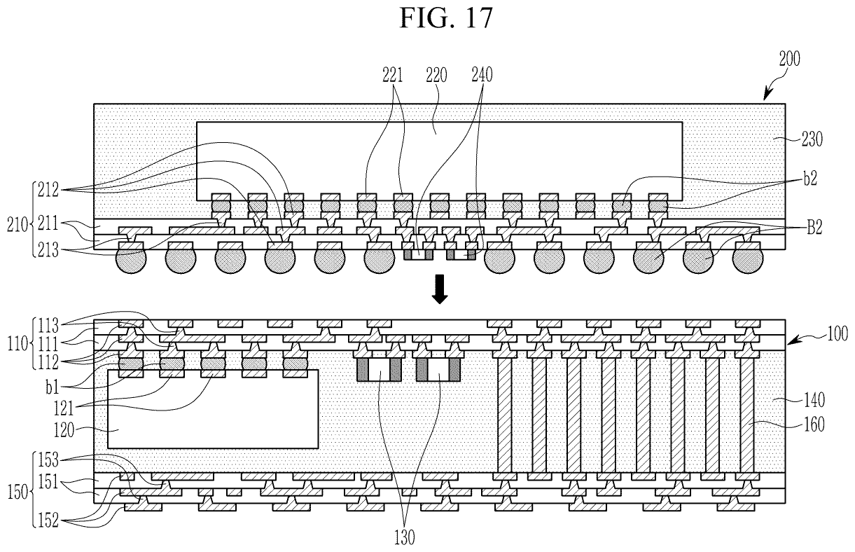

According to an embodiment, a conductive bump B1 may be formed on the second redistribution structure 150 after the second redistribution structure 150 is formed. However, the conductive bump B1 may be formed after the first semiconductor package 100 is bonded to the second semiconductor package 200 (see FIG. 17).

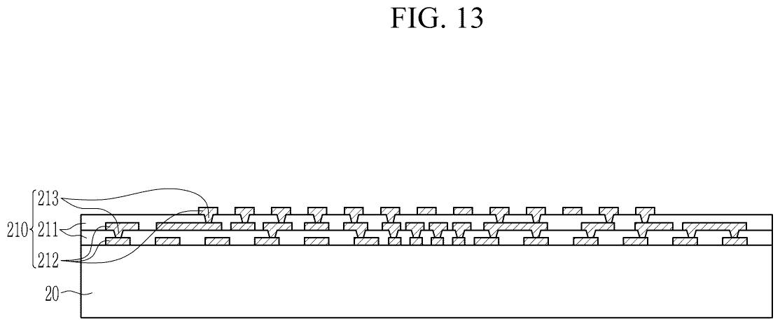

Referring to FIG. 13, a third redistribution structure 210 is formed. The third redistribution structure 210 may be formed on a carrier substrate 20. The third redistribution structure 210 may be manufactured by sequentially and repeatedly forming the insulating layer 211, the via 213, and the wiring layer 212 as necessary.

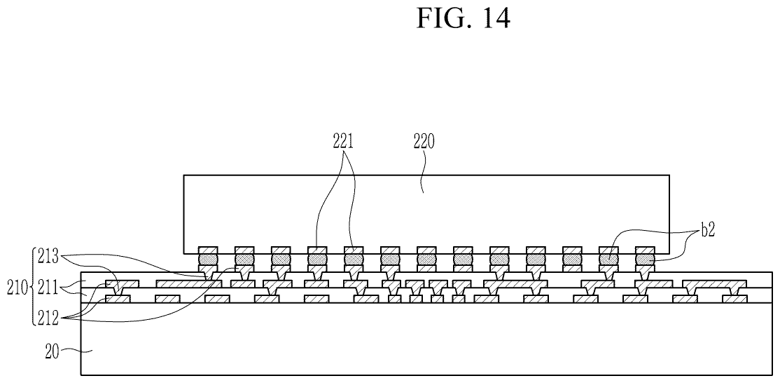

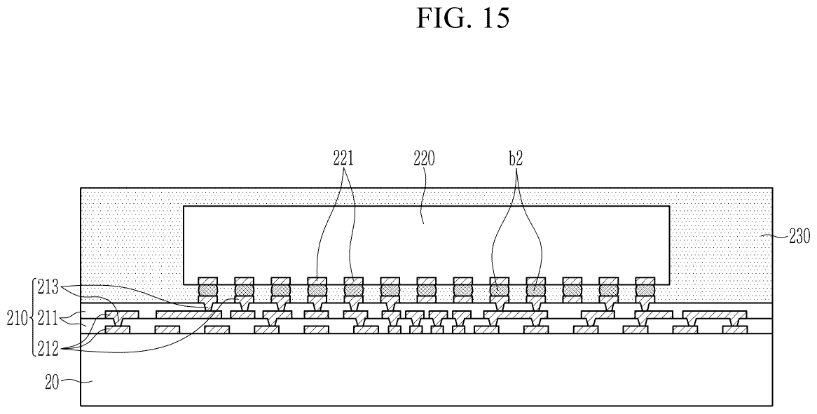

Next, referring to FIGS. 14 and 15, the second semiconductor chip 220 is disposed on the third redistribution structure 210, and the second encapsulant 230 on and at least partially covering the second semiconductor chip 220 is formed. The second encapsulant 230 may be formed by compression molding, transfer molding, and/or the like.

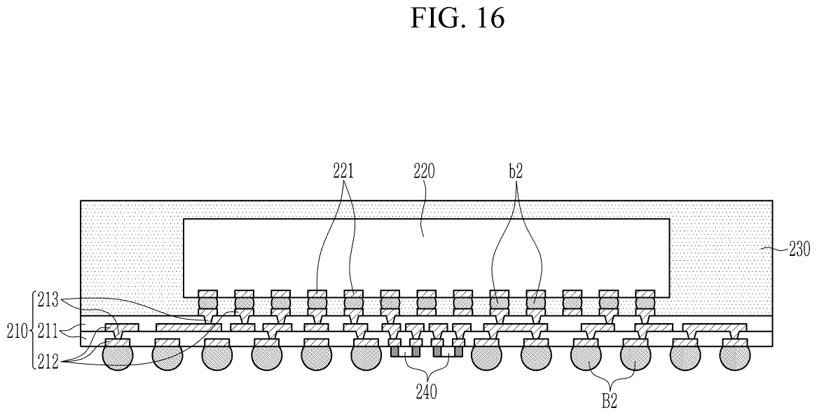

Next, referring to FIG. 16, after removing the carrier substrate 20, a conductive bump B2 is formed on the lower surface of the third redistribution structure 210, and the second passive component 240 is arranged as necessary to manufacture the second semiconductor package 200.

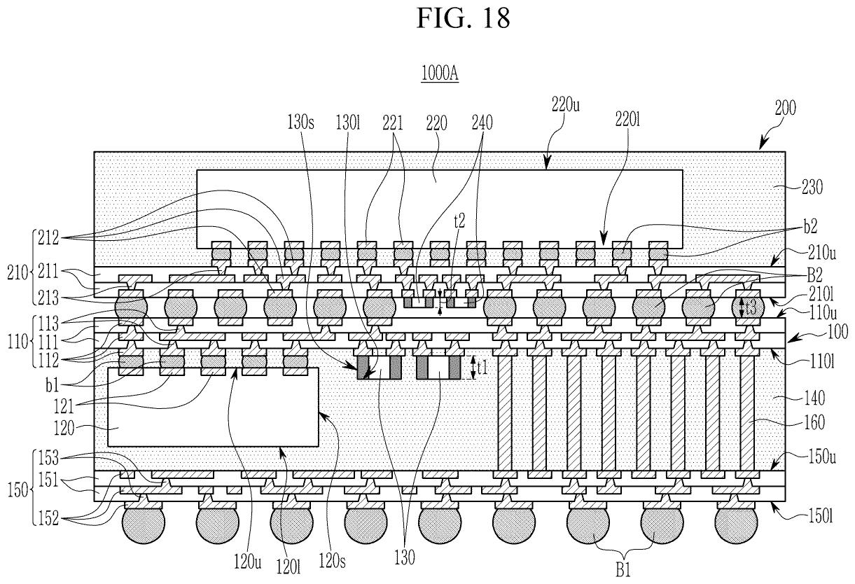

Finally, referring to FIGS. 17 and 18, by bonding the second semiconductor package 200 onto the first redistribution structure 110 of the first semiconductor package 100, the semiconductor package 1000A may be manufactured. The first semiconductor package 100 and the second semiconductor package 200 may be bonded through a conductive bump B2 positioned on a lower surface of the second semiconductor package 200.

According to an embodiment, a conductive bump B1 may be formed on the second redistribution structure 150 after bonding the first semiconductor package 100 and the second semiconductor package 200.

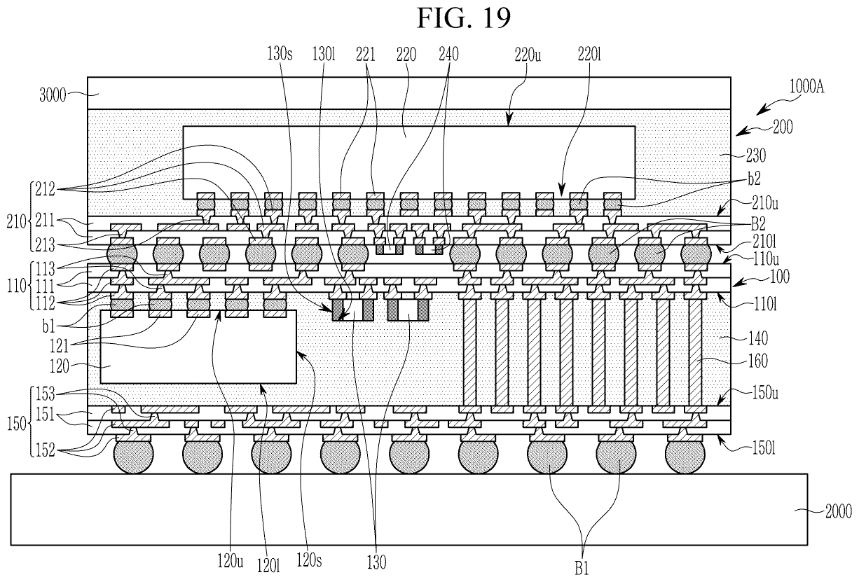

FIG. 19 illustrates a state in which the semiconductor package of FIG. 1 is assembled with a main board and a thermal interface material.

The semiconductor package 1000A may be mounted on the main board 2000. It will be understood that other components for configuring the device together with the semiconductor package 1000A may be disposed on the main board 2000 in accordance with various embodiments.

A thermal interface material (TIM) 3000 may be attached on the second semiconductor package 200 of the semiconductor package 1000A. The thermal interface material 3000 may be attached on the second encapsulant 230. When the second semiconductor chip 220 is exposed onto the second encapsulant 230 as in the case of the semiconductor package 1000B, the thermal interface material 3000 may extend and be attached to the second encapsulant 230 and the second semiconductor chip 220. According to the present disclosure, the semiconductor package 1000A may be connected to a heat sink in the device by directly bonding the thermal interface material 3000 on the second semiconductor package 200.

Although the embodiments of the disclosure have been described in detail above, the embodiments of the inventive concept are not limited to the scope of the present disclosure, but various modifications and improvements of the person of an order skill in the art using the basic concept of the present disclosure defined in the following claim range also are within the scope of the present disclosure.

In addition, the embodiments of the present disclosure are not independent of each other and may be implemented in combination unless particularly contradictory. Therefore, it should be considered that an embodiment in which one or more of the embodiments of the present disclosure are combined is also included in the embodiments of the inventive concept.

What is claimed is:

1. A semiconductor package comprising:
a first semiconductor package which comprises a first redistribution structure, a first semiconductor chip on a lower surface of the first redistribution structure, a first encapsulant on at least a portion of the first semiconductor chip, a second redistribution structure on the first encapsulant, and a conductive post electrically connecting the first redistribution structure and the second redistribution structure through the first encapsulant; and
a second semiconductor package which is on an upper surface of the first redistribution structure and comprises a third redistribution structure, a second semiconductor chip on the third redistribution structure, and a second encapsulant on at least a portion of the second semiconductor chip,
wherein the first encapsulant integrally covers each of a lower surface and a side surface of the first semiconductor chip.

2. The semiconductor package of claim 1, wherein:
the first semiconductor chip comprises a connection pad on an upper surface of the first semiconductor chip, and
the first semiconductor package further comprises a conductive bump which is between the first redistribution structure and the connection pad to electrically connect the first redistribution structure and the connection pad.

3. The semiconductor package of claim 1, wherein:
the first semiconductor package further comprises a first passive component on the lower surface of the first redistribution structure.

4. The semiconductor package of claim 3, wherein:
the first passive component is between the first semiconductor chip and the conductive post.

5. The semiconductor package of claim 3, wherein:
at least a portion of the first passive component overlaps the second semiconductor chip in a direction perpendicular to the upper surface of the first redistribution structure.

6. The semiconductor package of claim 3, wherein:
the first encapsulant further covers a lower surface and a side surface of the first passive component.

7. The semiconductor package of claim 3, wherein:
the second semiconductor package further comprises a second passive component on a lower surface of the third redistribution structure.

8. The semiconductor package of claim 7, wherein:
a number of the first passive component is greater than a number of the second passive component.

9. The semiconductor package of claim 7, wherein:
a thickness of the first passive component is greater than a thickness of the second passive component.

10. The semiconductor package of claim 1, wherein:
at least a portion of the conductive post overlaps the second semiconductor chip in a direction perpendicular to the upper surface of the first redistribution structure.

11. The semiconductor package of claim 1, wherein:
at least a portion of the first semiconductor chip overlaps the second semiconductor chip in a direction perpendicular to the upper surface of the first redistribution structure.

12. The semiconductor package of claim 1, wherein:
an upper surface of the second semiconductor chip is free of the second encapsulant.

13. The semiconductor package of claim 1, wherein:
the second semiconductor package further comprises a conductive bump which is on a lower surface of the third redistribution structure to electrically connect the third redistribution structure and the first redistribution structure.

14. The semiconductor package of claim 1, wherein:
the first semiconductor chip comprises a connection pad on an upper surface of the first semiconductor chip, and
the connection pad is in contact with the first redistribution structure.

15. The semiconductor package of claim 1, wherein:
the first semiconductor chip comprises a connection pad on the lower surface of the first semiconductor chip, and
the first semiconductor package further comprises a conductive wire electrically connecting the connection pad to the first redistribution structure.

16. A semiconductor package comprising:
a first semiconductor package which comprises a first redistribution structure, a memory chip on a lower surface of the first redistribution structure, a passive component spaced apart from the memory chip on the lower surface of the first redistribution structure, a first encapsulant on at least a portion of each of the memory chip and the passive component, a second redistribution structure on the first encapsulant, and a conductive post electrically connecting the first redistribution structure and the second redistribution structure through the first encapsulant; and
a second semiconductor package which is on an upper surface of the first redistribution structure and comprises a third redistribution structure, a logic chip on the third redistribution structure, and a second encapsulant on at least a portion of the logic chip,
wherein each of the memory chip, the passive component, and the conductive post is electrically connected to the logic chip through the first redistribution structure and the third redistribution structure.

17. The semiconductor package of claim 16, wherein:
the passive component comprises a capacitor.

18. A semiconductor package comprising:
a first redistribution structure;
a first semiconductor chip on a lower surface of the first redistribution structure;
a passive component on the lower surface of the first redistribution structure and spaced apart from the first semiconductor chip;
a first encapsulant on at least a portion of each of the first semiconductor chip and the passive component;
a second redistribution structure on the first encapsulant;
a conductive post that electrically connects the first redistribution structure and the second redistribution structure through the first encapsulant;
a second semiconductor chip on an upper surface of the first redistribution structure; and
a second encapsulant on at least a portion of the second semiconductor chip,
wherein the first encapsulant integrally covers each of a lower surface of the first semiconductor chip, a side surface of the first semiconductor chip, a lower surface of the passive component, and a side surface of the passive component.

19. The semiconductor package of claim 18, wherein:
the passive component is electrically connected to the second semiconductor chip through the first redistribution structure.

20. The semiconductor package of claim 18, wherein:
at least a portion of the passive component overlaps the second semiconductor chip in a direction perpendicular to the upper surface of the first redistribution structure.
